(19) United States
(12) Patent Application Publication
(10) Pub. No.: US 2021/0097218 A1
(43) Pub. Date: Apr. 1, 2021

(54) DATA PROCESSING SYSTEM AND METHOD

(71) Applicant: SIEMENS INDUSTRY SOFTWARE INC., Plano, TX (US)

(72) Inventors: George A. Allen, Okinawa (JP); Richard Charles Collins, Cambridge (GB); Diana Cox, Cambridge (GB); Lloyd Husbands, Cambridge (GB); David Jackson, Cambridge (GB); Peter Philip Lonsdale Nanson, Cambridge (GB)

(73) Assignee: SIEMENS INDUSTRY SOFTWARE INC., Plano, TX (US)

(21) Appl. No.: 17/098,340

(22) Filed: Nov. 14, 2020

Related U.S. Application Data
(62) Division of application No. 15/757,017, filed on Mar. 2, 2018.

(51) Int. Cl. G06F 30/20; G06T 19/00

(52) U.S. Cl. CPC G06F 30/20; G06F 2119/18; G06T 2210/32; G06T 19/00

(57) ABSTRACT

A method for representing a product using data in different data processing formats comprises deriving data relating to one or more first parts of the product in a first format and deriving data relating to one or more second parts of the product in a second format. The first format includes mesh data and the second format includes a classic geometric representation. In a data processing system, at least one first part of the product including mesh data is selected and at least one second part of the product including classic geometric representation data is selected.

### CROSS REFERENCE TO RELATED APPLICATIONS

This application is a divisional of and claims priority to pending U.S. application Ser. No. 15/757,017, filed Mar. 2, 2018, which application is the US National Stage of International Application No. PCT/CN2015/089076 filed Sep. 7, 2015, claims the benefit thereof. All of the applications are incorporated by reference herein in their entirety.

### TECHNICAL FIELD

This present disclosure relates to the general field of computer aided technologies (“CAx”) including computer aided design, drafting (“CAD”), engineering (“CAE”) manufacturing (“CAM”) and visualisation systems (individually and collectively “CAD systems”), product lifecycle management (“PLM”) systems, and similar systems, that manage data for products and other items (collectively, “Product Data Management” systems or PDM systems).

### BACKGROUND OF THE DISCLOSURE

PDM systems manage PLM and other data. Improved methods and systems are desirable.

### SUMMARY OF THE DISCLOSURE

Various disclosed embodiments include methods for representing a product using data in different data processing formats. The method comprises deriving data relating to one or more first parts of the product in a first format and deriving data relating to one or more second parts of the product in a second format. The first format comprises mesh data and the second format comprises a classic geometric representation. In a data processing system, at least one first part of the product comprising mesh data is selected and at least one second part of the product comprising classic geometric representation data is selected. A representation of the product including the selected first and second parts is provided.

A method includes defining a point on a mesh representation of a part of a product and communicating the point to a boundary representation model. The method comprises obtaining a mesh data representation relating to a part of the product, the mesh data representation comprising a plurality of triangles each representing a facet. A natural parameterisation of each triangle of the mesh data representation is extracted, the natural parameterisation comprising an integer identifier of each facet and associated facet parameters and the facet parameters comprising a pair of u, v coordinates. A modified parameterisation is derived for each triangle of the mesh data representation of the part comprising a combination of the integer identifier and the facet parameters. The modified parameterisation is communicated to the boundary representation model; and, storing the modified parameterisation of the scan data.

In accordance with a first aspect, a method of representing a product using data in different data processing formats comprises deriving data relating to one or more first parts of the product in a first format; deriving data relating to one or more second parts of the product in a second format; wherein the first format comprises mesh data and wherein the second format comprises a classic geometric representation; in a data processing system, receiving instructions of a selection of at least one first part of the product comprising mesh data; in the data processing system, receiving instructions of a selection of at least one second part of the product comprising data classic geometric representation; and, providing a representation of the product including the selected first and second parts.

Different parts of a product are modelled in different data processing formats and a representation of the product is provided without any change to the format in which each of the parts was originally represented, i.e. facet data and classic geometric representation data are attached to a boundary representation model and modelling operations applied in the format in which the data is held. This helps to maintain the original design intent, as well as reducing costs and errors caused by format conversion.

A modelling operation may be applied to one or more of the parts.

The method may further comprise applying an offset to one or more of the parts of the product. In one embodiment, where the mesh data represents an outer wall of the product, the result of applying the offset comprises mesh data forming an inner wall.

The method may further comprise applying features to one or more of the parts of the product via Boolean operations. The features may comprise a classic geometric representation.

The derived mesh data may be supplied to a data processing system from a separate source. The mesh data may be derived from a physical sample of the part. The mesh data may be derived by scanning a physical sample of the part.

The method may further comprise storing the mesh data in a store as a collection of facets. The classic geometric representation may be derived by simulation in the data processing system.

The method may further comprise receiving instructions of a selection of at least one part of the product for modification; if the selected part comprises a classic geometric representation, then applying a classic geometric modification to the geometric representation of the part; if the selected part comprises mesh data applying a facet based modification to the mesh data of the part; and, providing a representation of the modified part.

Modifications may be applied to any of the parts of the product, but the modifications are made to representations in the same format as the representation was originally generated, improving efficiency and maintaining the quality of the representation, as compared with having to convert a representation of a part from one format to another.

The modification may comprise a modelling operation. The modelling operation may be applied to an object comprising both mesh data and a classic geometric representation. The method may further comprise storing the representation of the product.

The method may further comprise extracting data from the representation of the product and generating manufacturing instructions for a manufacturing process.

Having obtained the representations in their different formats and continued the design process by applying any necessary modifications to each part, suitable manufacturing instructions may be generated. The manufacturing instructions may comprise instructions for additive manufacturing.

The method may further comprise extracting data from the representation of the product and determining at least one of fit or clearance between the parts of the product, or mass properties of the product. The method may further comprise extracting data from the representation of the product and generating an image for display, or exporting data for further processing.

In accordance with a second aspect, a data processing system having at least a processor and accessible memory, the data processing system configured to represent a product, the representation comprises deriving data relating to one or more first parts of the product in a first format; deriving data relating to one or more second parts of the product in a second format; wherein the first format comprises mesh data and wherein the second format comprises a classic geometric representation; in a data processing system, receiving instructions of a selection of at least one first part of the product comprising mesh data; in the data processing system, receiving instructions of a selection of at least one second part of the product comprising a classic geometric representation; and, providing a representation of the product including the selected first and second parts.

The system may further comprise a display configured to output the representation of the product. The system may further comprise a store to store the representation of the product.

In accordance with a third aspect, a non-transitory computer-readable medium encoded with executable instructions that, when executed, cause one or more data processing systems to perform a method of modelling a product comprises deriving data relating to one or more first parts of the product in a first format; deriving data relating to one or more second parts of the product in a second format; wherein the first format comprises mesh data and wherein the second format comprises a classic geometric representation; in a data processing system, receiving instructions of a selection of at least one first part of the product comprising mesh data; in the data processing system, receiving instructions of a selection of at least one second part of the product comprising data classic geometric representation; and, providing a representation of the product including the selected first and second parts.

In accordance with a fourth aspect, a method of defining a point on a mesh representation of a part of a product and communicating the point to a boundary representation model, the method comprises obtaining a mesh data representation relating to a part of the product, the mesh data representation comprising a plurality of triangles each representing a facet; extracting a natural parameterisation of each triangle of the mesh data representation, the natural parameterisation comprising an integer identifier of each facet and associated facet parameters, the facet parameters comprising a pair of u, v coordinates; deriving a modified parameterisation for each triangle of the mesh data representation of the part comprising a combination of the integer identifier and the facet parameters; communicating the modified parameterisation to the boundary representation model; and, storing the modified parameterisation of the scan data.

The step of deriving a modified parameterisation may comprise identifying first, second and third vertices of each facet, identifying first and second axes of each facet and defining a unique point within the facet as the sum of the origin, a constant multiple of the first axis and a constant multiple of the second axis, where the constants are greater than or equal to zero and the sum of the constants is less than or equal to one.

The method may further comprise providing an updated representation of the modelled part.

The method may further comprise, in response to a position request consequent to a user input receiving instructions of a selection of a point on the mesh representation of the modelled part, communicating the integer facet identifier and the unique point together to the boundary representation model to identify the point on the mesh. The integer facet identifiers may be mapped onto a spiral of unit squares about the origin. Two facets may be mapped to each square.

Each triangle in the unit square may be discrete and separated from a boundary of the unit square. The modified parameterisation may comprise an affine transformation of the internal facet parameters of each facet.

The mesh data may be obtained from a physical sample of the part. The mesh data may be derived by scanning the physical sample.

In accordance with a fifth aspect, a data processing system having at least a processor and accessible memory, the data processing system configured to define a point on a mesh representation of a part of a product and communicate the point to a boundary representation model, the method comprising obtaining a mesh data representation relating to a part of the product from a physical sample of the part, the mesh data representation comprising a plurality of triangles; extracting a natural parameterisation of each triangle of the mesh data representation, the natural parameterisation comprising an integer identifier of each facet and associated facet parameters, the facet parameters comprising a pair of u, v coordinates; deriving a modified parameterisation for each triangle of the mesh data representation of the part comprising a combination of the integer identifier and the facet parameters; communicating the modified parameterisation in response to a position request consequent to a user input receiving instructions of a selection of a point on the boundary representation model; and, providing an updated representation of the modelled part.

The system may further comprise a display configured to output the representation of the modelled part. The system may further comprise a store to store the representation of the modelled part.

In accordance with a sixth aspect a non-transitory computer-readable medium encoded with executable instructions that, when executed, cause one or more data processing systems to perform a method to define a point on a mesh representation of a part of a product and communicate the point to a boundary representation model, the method comprising obtaining a mesh data representation relating to a part of the product from a physical sample of the part, the mesh data representation comprising a plurality of triangles; extracting a natural parameterisation of each triangle of the mesh data representation, the natural parameterisation comprising an integer identifier of each facet and associated facet parameters, the facet parameters comprising a pair of u, v coordinates; deriving a modified parameterisation for each triangle of the mesh data representation of the part comprising a combination of the integer identifier and the facet parameters; communicating the modified parameterisation in response to a position request consequent to a user input receiving instructions of a selection of a point on the boundary representation model; and, providing an updated representation of the modelled part.

The foregoing has outlined rather broadly the features and technical advantages of the present disclosure so that those skilled in the art may better understand the detailed description that follows. Additional features and advantages of the disclosure will be described hereinafter that form the subject of the claims. Those skilled in the art will appreciate that they may readily use the conception and the specific embodiment disclosed as a basis for modifying or designing other structures for carrying out the same purposes of the present disclosure. Those skilled in the art will also realize that such equivalent constructions do not depart from the scope of the disclosure in its broadest form.

Before undertaking the DETAILED DESCRIPTION below, it may be advantageous to set forth definitions of certain words or phrases used throughout this patent document: the terms “include” and “comprise,” as well as derivatives thereof, mean inclusion without limitation; the term “or” is inclusive, meaning and/or; and the term “controller” means any device, system or part thereof that controls at least one operation, whether such a device is implemented in hardware, firmware, software or some combination of at least two of the same. It should be noted that the functionality associated with any particular controller may be centralized or distributed, whether locally or remotely. Definitions for certain words and phrases are provided throughout this patent document, and those of ordinary skill in the art will understand that such definitions apply in many, if not most, instances to prior as well as future uses of such defined words and phrases. While some terms may include a wide variety of embodiments, the appended claims may expressly limit these terms to specific embodiments.

### BRIEF DESCRIPTION OF THE DRAWINGS

An example of method and data processing system according to the present disclosure will now be described with reference to the accompanying drawings in which:

FIG. 1 is a block diagram of a data processing system in which an embodiment can be implemented;

FIG. 2 illustrates terminology used with respect to this disclosure;

FIG. 3 illustrates an example of a product to be designed;

FIG. 4 illustrates the part of FIG. 3 after scanning;

FIG. 5 illustrates the scanned part of FIG. 3 after conversion to a geometric representation;

FIGS. 6a to 6e illustrate the steps involved in a conventional part modelling process;

FIG. 7 illustrates a scanned part in accordance with the disclosed embodiments;

FIG. 8 illustrates the part of FIG. 7 in more detail in accordance with the disclosed embodiments;

FIG. 9 illustrates a finished part in accordance with the disclosed embodiments;

FIGS. 10a to 10d illustrate the process steps in an exemplary method for producing a part in accordance with the disclosed embodiments;

FIG. 11 is a flow diagram of a process in accordance with disclosed embodiments.

FIG. 12 illustrates production of a modified parameterisation of mesh scan data to use in an exemplary method in accordance with the disclosed embodiments;

FIG. 13 shows part of FIG. 12 in more detail; and,

FIG. 14 is a flow diagram of a process in accordance with the disclosed embodiments.

### DETAILED DESCRIPTION

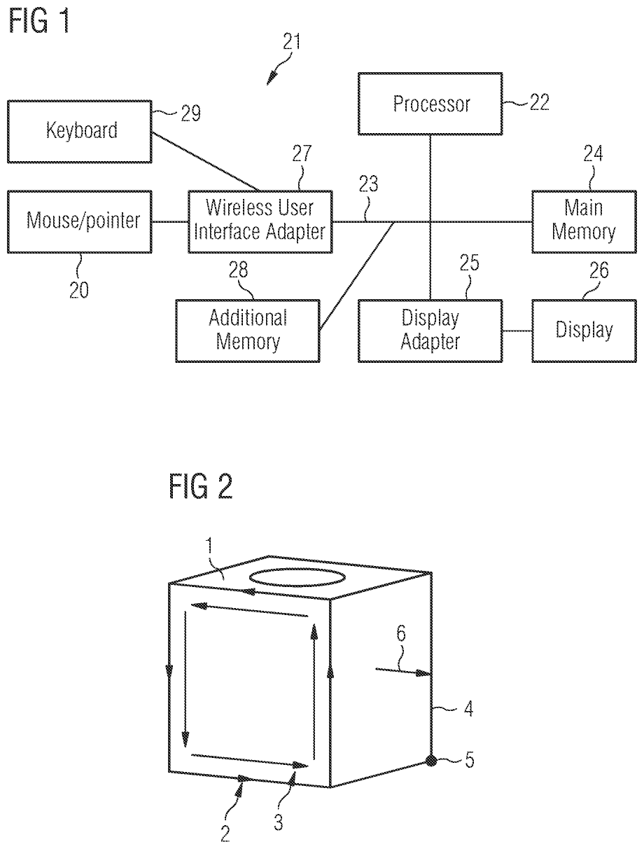

The embodiments of FIGS. 1 to 14 used to describe the principles of the present disclosure in this document are by way of illustration only and should not be construed in any way to limit the scope of the disclosure. Those skilled in the art will understand that the principles of the present disclosure may be implemented in any suitably arranged device, apparatus, system, or method.

FIG. 1 illustrates an example of a data processing system in which an embodiment of the present disclosure may be implemented, for example a CAD system configured to perform processes as described herein. The data processing system 21 comprises a processor 22 connected to a local system bus 23. The local system bus connects the processor to a main memory 24 and graphics display adaptor 25, which may be connected to a display 26. The data processing system may communicate with other systems via a wireless user interface adapter connected to the local system bus 23, or via a wired network, e.g. to a local area network. Additional memory 28 may also be connected via the local system bus. A suitable adaptor, such as wireless user interface adapter 27, for other peripheral devices, such as a keyboard 29 and mouse 20, or other pointing device, allows the user to provide input to the data processing system. Other peripheral devices may include one or more I/O controllers such as USB controllers, Bluetooth controllers, and/or dedicated audio controllers (connected to speakers and/or microphones). It should also be appreciated that various peripherals may be connected to the USB controller (via various USB ports) including input devices (e.g., keyboard, mouse, touch screen, trackball, camera, microphone, scanners), output devices (e.g., printers, speakers), or any other type of device that is operative to provide inputs or receive outputs from the data processing system. Further it should be appreciated that many devices referred to as input devices or output devices may both provide inputs and receive outputs of communications with the data processing system. Further it should be appreciated that other peripheral hardware connected to the I/O controllers may include any type of device, machine, or component that is configured to communicate with a data processing system.

An operating system included in the data processing system enables an output from the system to be displayed to the user on display 26 and the user to interact with the system. Examples of operating systems that may be used in a data processing system may include Microsoft Windows™, Linux™, UNIX™, iOS™, and Android™ operating systems.

In addition, it should be appreciated that data processing system 21 may be implemented as in a networked environment, distributed system environment, virtual machines in a virtual machine architecture, and/or cloud environment. For example, the processor 22 and associated components may correspond to a virtual machine executing in a virtual machine environment of one or more servers. Examples of virtual machine architectures include VMware ESCi, Microsoft Hyper-V, Xen, and KVM.

Those of ordinary skill in the art will appreciate that the hardware depicted for the data processing system 21 may vary for particular implementations. For example the data processing system 21 in this example may correspond to a computer, workstation, and/or a server. However, it should be appreciated that alternative embodiments of a data processing system may be configured with corresponding or alternative components such as in the form of a mobile phone, tablet, controller board or any other system that is operative to process data and carry out functionality and features described herein associated with the operation of a data processing system, computer, processor, and/or a controller discussed herein. The depicted example is provided for the purpose of explanation only and is not meant to imply architectural limitations with respect to the present disclosure.

The data processing system 21 may be connected to the network (not a part of data processing system 21), which can be any public or private data processing system network or combination of networks, as known to those of skill in the art, including the Internet. Data processing system 21 can communicate over the network with one or more other data processing systems such as a server (also not part of the data processing system 21). However, an alternative data processing system may correspond to a plurality of data processing systems implemented as part of a distributed system in which processors associated with several data processing systems may be in communication by way of one or more network connections and may collectively perform tasks described as being performed by a single data processing system. Thus, it is to be understood that when referring to a data processing system, such a system may be implemented across several data processing systems organized in a distributed system in communication with each other via a network.

In this description, the following terms are used, with reference to the example of FIG. 2. A face 1 is a bounded subset of a surface, whose boundary is a collection of zero or more loops 2. A face with zero loops forms a closed entity, such as a full spherical face. A loop 2 is a connected component of a face boundary. A loop can have fins 3. A fin represents the oriented use of an edge 4 by a loop 2. An edge 4 is a bounded piece of a single curve. Its boundary is a collection of zero, one or two vertices 5. A vertex represents a point in space. Arrow 6 is a face normal. A facet is a triangular region of a plane. A mesh is a connected collection of facets.

Boundary representation (B-rep) technology dominates computer aided design (CAD) modelling. The B-rep technology provides an efficient and adaptable representation of parts by combining classic geometry: analytic surfaces and curves, non-uniform rational basis spline (NURBS) and procedural surfaces and curves; with topology, which captures the connectivity and interaction between geometric elements. However, B-rep technology is not well suited to replicating organic shapes, to reverse engineering workflows which start from a scan of an existing part, or to the early stages of conceptual design, especially for styling. A problem with digital simulations is that “soft” features of a design, such as the tactile feel of the product to the user or comfort of the product, for example the feel of a handle of a tool, or the casing of a mobile phone, or computer mouse, cannot be perceived by the user from a simulation and so these parts of the product are normally designed in physical media, such as wood, clay or wax. Reverse engineering may be needed to create replacement components to maintain equipment which has outlived the original company that made the component, or where the original engineering drawings have been lost. Another future source of scanned data is for generation of replacement parts for surgery, for example knee or tooth replacements, or custom fit design using data from body scanners.

Furthermore, additive manufacturing has introduced a further class of shapes whose complexity is ill-suited to the limitations of traditional geometric representations. While such shapes can be represented efficiently by a mesh, the use of facets to represent a shape suffers from the converse problem—facets are an inefficient mechanism for representing analytic geometry, and are not naturally suited to parametric editing or feature modelling.

Conventionally, the problem of the different requirements during product design has been addressed by converting to a single format. This may be done, for example, by converting the meshes to NURBS, which is time consuming and frequently requires significant user intervention; by converting each facet to a triangular planar face, which increases model size hugely and incurs a significant performance overhead for later operations; or, in the other direction, by converting the exact geometry to mesh which is inaccurate and loses important detail (e.g. the radius of a hole), or adds features not originally present, such as chamfers on cubes. There may also be further degradation if a modification is subsequently applied, as the facets no longer retain the symmetry of the shape when a modification is applied to an exact geometry that has been converted to be represented as a mesh.

As can be understood from the discussion above, a user of a CAD system may be working on a product design where there is a requirement for modelling the design of the product using data obtained in more than one modelling format, but all of the ways of achieving this to date, have drawbacks.

As set out in more detail below, this disclosure addresses the problem by using a model which defines a new surface type to represent a mesh. The new surface type can be associated with a face in the same manner as a classic surface is associated with a face, so allowing a mesh to be used as the surface of a face. A new curve type is also defined, comprising a connected collection of line segments, which is termed a polyline. The new curve type can be associated with an edge in the same manner as any curve, or with a fin, in the same way as an SP-curve (surface parameter-space curve, i.e. a 3d curve resulting from embedding a 2d curve in the parameter space of a surface, which represents curves “drawn” on to a surface). The polyline can be used as the curve of a fin in a face whose surface is a mesh; or a polyline can be used as the curve of an edge, all of whose adjacent faces have mesh surfaces. The mesh is then treated as a surface in a B-rep model and the polylines is used as a curve in a B-rep model. In this way, a single model is able to contain both facet and classic geometry, enabling the design intent to be preserved, together with the strengths of both formats. A faceted sheet or solid body, or other types of body such as wireframe, general (non-manifold) or mixed dimension (possessing a mixture of wireframe, sheet and/or solid portions) bodies may also be handled in the model.

For convenience, edges between faces with facet geometry may be treated as being always accurate and “watertight”, i.e. all polyline vertices are facet vertices in both meshes and the facet vertex positions of each mesh along the edge are the same. However, this approach need not always be taken. The mechanisms for handling edges and vertices between surfaces which do not meet exactly can be extended to handle edges between meshes and classic surfaces. These edges are typically tolerant, with an SP curve on one fin and a polyline on the other.

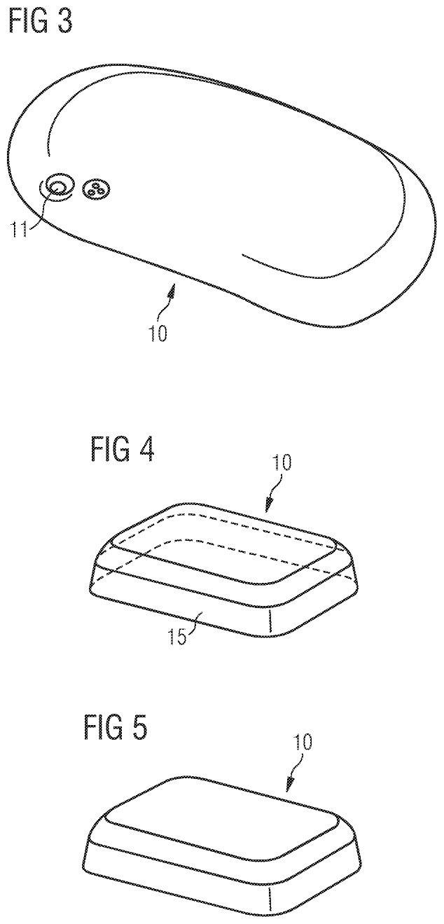

An example of a method of representing a product according to the present disclosure may be illustrated by an example of a design for a mobile phone, or computer mouse shell. The designer typically begins by modelling the outer shape and feel of a shell 10 in wood or clay, as shown in FIG. 3. In a wooden model for a mobile phone shell, features, such as camera lens openings 11, or an on/off switch may be carved, so that the designer can determine empirically whether the chosen position and shape is comfortable, or interferes with the user's normal way of holding the phone. For a computer mouse, representations of the mouse keys may be carved in wood, or moulded in clay, in the surface. When a satisfactory result has been obtained, the shell 10 is scanned, as illustrated by FIG. 4, so is naturally represented by facets. Conventionally, this scanned shell has had to be converted to a surface, or classic geometry, within the CAD model, as shown in FIG. 5, before it could be further processed. Conversely, if the outer shell had been designed in a CAD system, then a physical model would have had to be produced, for example by numerical control (NC) milling or 3-D printing, in order to test its “feel”, extending the design lifecycle significantly, as the same would have to be done for any changes to the external design made in the CAD system.

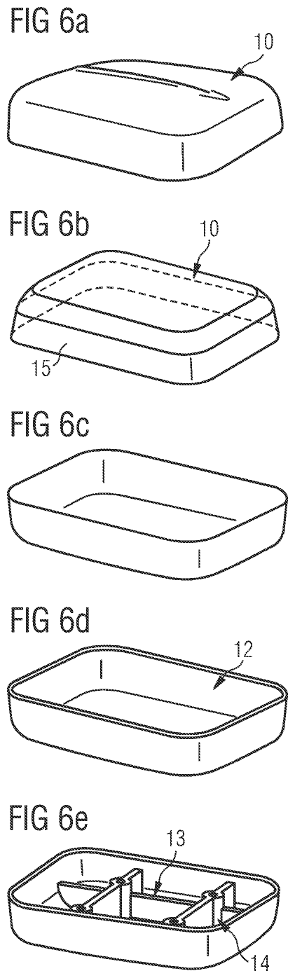

The full conventional process is illustrated graphically in FIGS. 6a to 6e. The carved or moulded external shape 10 is provided as a physical embodiment made from a medium such as wood or clay, as shown in FIG. 6a. The physical product 10 is scanned, as shown in FIG. 6b and the scanned data is imported into a CAD system, where it is converted, i.e. surfaces are constructed which match the scan data, as shown in the image of FIG. 6c. An offset is applied to generate inner walls 12 as shown in FIG. 6d and structural details, such as ribs 13 and bosses 14, are added as shown in FIG. 6e. Thus, the exterior surface 15 of the shell 10 is naturally represented by facets, but for all later stages of the processing, those facets have been converted to surfaces, or classic geometry, for further processing. Using a conventional CAD model, the workflow described above requires conversion of the outer shape to a curved-surface model before proceeding, because current modelling operations, such as offsetting and Booleans, do not work on a mixture of facets and classic surfaces. Converting faceted models to curvy ones, i.e. converting to surfaces, slows down the development of products and tooling, which can be frustrating for users and costly to the business.

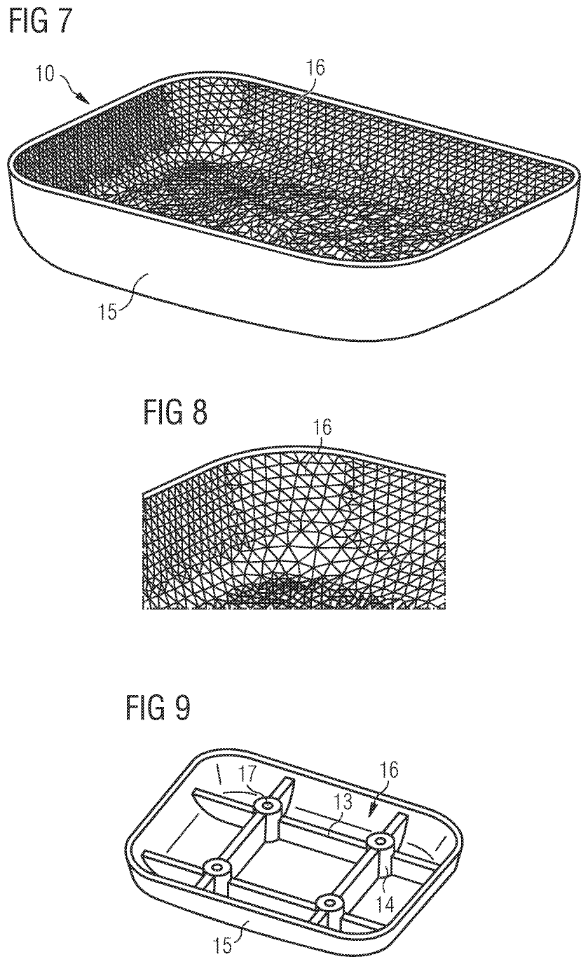

The distinction of the present method can be seen more clearly in FIG. 7, in that offsetting, or shelling, or thickening operation and detailing is applied directly to the faceted model obtained from scanning. The offset is applied to the thin-walled shell 10 which has been generated from the scanned physical object, in order to make inner walls for the scanned outer wall. This offset is applied to the faceted scanned shape 15, without any conversion of the scanned shape to a surface representation. The faceting on the inner surface 16, seen in FIGS. 7 and 8, may be fairly coarse, since its shape is not particularly critical, as long as the inner surface is a roughly constant distance from the outer surface. Further design steps may include part modelling, such as creating some ribs 13 and bosses 17 on the inside of the shell, to strengthen the structure and provide mounting points for various components, as illustrated by FIG. 9. For this, classic surface representations are used, rather than a mesh. The interior geometry is created using rib and boss features, which require that the geometry kernel supports extrusions, drafts and Booleans. The end result of the process described above is a B-rep with a mixture of facet and classic geometry. Faces 15, 16 are meshes, collections of facets, but faces 14, 17 are analytic cones and cylinders respectively.

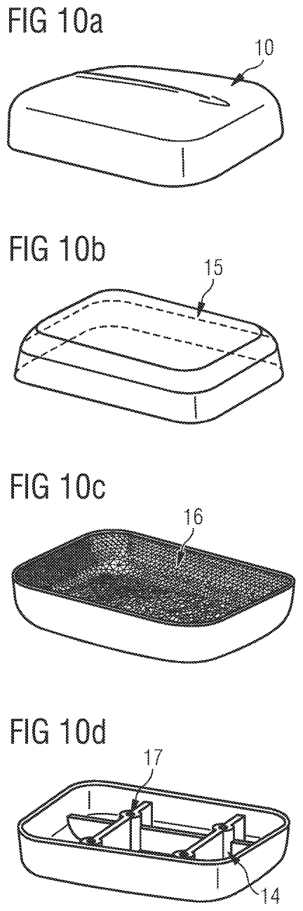

A summary of the steps in the method of the present disclosure is illustrated in FIGS. 10a to 10d. A physical model 10 is created, as shown in FIG. 10a, typically from clay or wood, but other materials may be used. A scan 15 of the external shape of the physical model is generated as illustrated in FIG. 10b. The scanned shape is facet data, represented as a mesh, or collection of points forming polygons, in this example, triangles. An inner surface 16 is formed, also represented as a mesh, shown in FIG. 10c. Thereafter, parts required for the interior are modelled using a classic geometric representation, rather than a facet based one, shown in FIG. 10d. The examples shown here being analytic cones 14, or cylinders 17. The user interface is able to carry out modelling operations on the different surface types, whether mesh, or cylinder or cone. The CAD functions may be applied directly to any of the objects, whether analytic or faceted. Data can be processed by the boundary representation model whether in mesh format or classic geometry format and the method copes with product represented in more than one data processing format, without the need for conversion.

FIG. 11 is a flow diagram of a typical method of modelling a product using more than one data format. The first stage is for the designer to generate 50 the physical model, for example from wood or clay. When the designer is happy with the form of the physical model, the model is scanned 51 and the scanned data, which is facet based data, is then available for further processing. The data may be stored 52 elsewhere, for example if the scanning is an offline process carried out by another part of the design team, and later supplied to the data processing system, or transferred directly to the data processing system from the scanner in a continuous process and stored in memory in the data processing system. The scanned mesh data represents the outer surface of the product in fine detail, but further layers are required. An inner surface, also mesh data, is generated 53, which may have coarser resolution than the scanned outer surface, provided that the inner surface is formed approximately at the same thickness all over. Once the outer and inner meshes have been dealt with, the designer determines 54 what, if any, additional features or details are required. These additional parts may be fittings or similar features, such as screw holes, or bosses and they may have to fit or match other fittings being produced separately, so designing these using classic geometry type models, rather than facet based modelling gives more accurate and reproducible results. Having generated all of the required parts of the product, whether from scanned data or geometric models, a representation of the complete product is provided 55, for example, as an image on a display, as well as, or in place of, stored data in a form which can be manipulated. During the process, the user may display individual parts, or groups of parts until all the required parts have been dealt with.

Once a representation of the product has been obtained, combining both data obtained from the physical model and the geometric model, the designer may wish to make changes. If modifications are required 56, the designer determines which part and what format of data is available for that part (mesh or classic geometry) and the designer works 57 on each part in need of modification in the format in which that data is held. There is no need for the designer to change the outer appearance, or inner surface from facet data to classic geometry in order to make changes, nor does the designer have to change the classic geometry which defines, for example, the screw holes, or bosses, into facet based data to be able to modify them. Once the modification is complete a representation of the modified product may be provided 58, keeping the mesh and classic geometry data in their separate formats. If required, the designer is also able to produce separate representations of each part that is being worked on during the process of modifying the product. At the end of the design process for the product, which may include the design process for any equipment with which it must interact, manufacturing instructions may be generated 59, suitable for a machine that is to manufacture the products, or parts thereof. Although the modification has been described with respect to inputs from the designer, in practice some of the steps described above may be carried out by the CAD system, as individual changes may be determined by the system in response to new or additional criteria.

The present disclosure provides a method which allows the design to be produced without the need to convert facets and meshes to classic surface geometry. This is attractive to users. Modifications to the meshes can be made using downstream functions in the model which are able to operate on faceted models. Modifications to the classic geometry features are carried out using downstream functions which are compatible with classic geometry models because the different data formats are modelled separately.

Although the examples described herein relate to a method which uses scan data for the part of the product in mesh format, previously stored legacy mesh data may be processed using the techniques of this disclosure. There may even be some features of the product which are generated in the CAD model as mesh data and these too can be processed without the need for conversion.

In another example, a model may be used for additive manufacturing. In this case, the manufacturing instructions 59 are provided to the printer, these instructions being facet based and the data extracted from the physical model is also facet based, so there is no potential inefficiency or loss of data relating to the external surface of the product, which the conventional requirement to convert from facet based to a classic boundary representation model and back again might introduce. A model optimized for additive manufacture may contain a volume filled with a lattice, for which facets are a lighter weight and more efficient representation, as well as other volumes bounded by classic geometry. For example, rather than starting with a mesh from a scanned physical item, optimising a model for additive manufacturing may start with classic geometry and modelling techniques to define the shape bounding the lattice, and then generate that lattice as facets based on physical and manufacturing properties. Some classic geometry may be retained, or added subsequently, to represent traditionally (subtractive) machined pieces of the part e.g. holes drilled into the printed volume. Retaining these different formats provides a light weight representation, efficient editing and use for assembly constraints. For example, when designing a part in context of other parts, assembly constraints are used to ensure the parts match correctly e.g. that parts joined by bolts have aligned holes of the same bore. The best way to represent such parts is to use classic geometry. The holes may then be formed by a 3d printer consuming them as facets, or the holes may be subsequently drilled, but keeping them as classic geometry during the design process allows the design intent to be preserved and documented.

Mechanisms for orphan geometry or construction geometry to handle the new geometry types are also extended by the method of this disclosure. Orphan geometry is geometry with no associated part and construction geometry is geometry associated with a part, but without specific local topology. As well as extending the representation, associated low level utilities are enhanced. These provide the infrastructure required for both modelling operators and application functionality.

Examples of the low level utilities which may be enhanced include connectivity enquiries, enquiries on the links between facet geometry and topology, and basic geometric enquiries such as extent and closure of polylines, or coincidence checks, or other enquiries of this type, or mass properties of parts with facet geometry. Validity checking provides functionality to check the geometric validity of meshes and polylines and functionality to check that the topological and geometric connectivity of a part are consistent. Rendering may amount to view independent rendering of parts with facet geometry, or view dependent and hidden line rendering of parts with facet geometry, such as silhouette generation on facet geometry, or perspective views, or output of facets from parts with facet geometry, which may require refining the facets to satisfy visualization parameters. Selection may include selection of topology with facet geometry and direct selection of facet geometry.

Other low level utilities which may be enhanced are data storage and retrieval, both of parts, and of partitions and deltas, containing facet geometry, providing support for on demand loading of meshes to minimize memory overheads, functionality to import facets from other formats, functionality to generate bounding topology for collections of facets, or functionality to refine this topology based on geometric criteria. Rollback provides support for undo and history based modelling. Boxing provides functionality to calculate axis aligned and non-aligned boxes and spatial indices for meshes and polylines, and faces and edges to which they are attached. Containment provides functionality to determine whether a point lies within a region, face or edge. Clashing provides functionality to efficiently determine whether two sets of topology clash and intersections provides functionality to intersect meshes with meshes, polylines, and classic surfaces or curves, or functionality to intersect polylines with meshes, polylines, and classic surfaces or curves.

Additional low level utilities which may be enhanced include projection to provide code to project a curve onto a mesh, along a vector or to the closest image; or mesh and polyline extension to provide functionality to extend “external” boundaries of a mesh. Filling holes in meshes provides functionality to repair holes in meshes, to a selected level of continuity and mesh repair provides functionality to repair degenerate or folded facets and to resolve self-intersections in meshes and polylines. Extrusion provides functionality to extrude a body with facet geometry into a sheet or solid and the extent of the extrusion may be determined by distances, surfaces or parts.

Sweeping enables a sweeping of a polyline or mesh or facet wireframe or sheet body along a path formed from one or more curves. The sweeping may be with variable twist or scale, controlled by law or guide curves orientation, or with variable orientation, controlled by supplied vectors, geometric or topological entities. Transformation functionality is provided to transform facet geometry. Mid-surface generation provides functionality to calculate a mesh which is a (weighted) average of two input meshes. Match mesh boundaries provides functionality to adjust mesh boundaries so they match along common polylines and optionally adjust the matched meshes to increase the smoothness of the join. Taper provides functionality to generate isocline curves for meshes and to generate taper rulings from such curves. There may be conversion between facet and classic geometry. Functionality to apply variable deformations to meshes and polylines may be provided.

Facet enabling the kernel modelling operators also has changes in the following areas: imprinting an edge on a face with facet geometry requires some additional steps beyond those required for classic geometry. The mesh has to be split along a polyline corresponding to the curve and then re-triangulated. The edge polylines need to be split at points corresponding to new vertices. Degenerate triangles need to be removed from the mesh. As described with respect to FIG. 10 above, offset, hollow and thicken is dealt with by providing specific functionality for offsetting meshes, resolving local self-intersections and adding blend-like regions at any sharp fins. Functionality may be added to trigger mesh extension or fill holes as required when offsets deviate at a sharp edge. Functionality to match meshes when offsetting adjacent mesh faces which meet along near smooth edges may be provided and functionality to calculate ruled mesh geometry for step faces and thicken sidewalls. Local transform functionality, to trigger mesh extension at sharp edges, or to fill holes as required when transforming subsets of parts, or to apply different transforms to different faces, may be provided. Replace face and patch functionality may be provided, as may a functionality to calculate the valid regions of self-intersecting faces. There may be outline and spun outline with required additional functionality to handle edge-on meshes and blending functionality to resolve blend interactions. External facet formats may be supported in order to reduce data redundancy and ease integration. The mesh data in these external formats may be represented to either single or double precision. Functionality to convert single precision data to and from double precision, while maintaining model consistency, is provided.

As can be understood from the embodiments of this disclosure performance improvements may be achieved by avoiding conversion between formats, whilst maintaining design intent. The various portions of the model can be represented in their natural formats and edited using the appropriate tools. For example, if a face is represented as a trimmed cylinder, then extending it can trivially maintain this shape, which would not be the case if the trimmed cylinder were to be represented as a mesh, as the facets no longer retain the symmetry of the shape.

Different components of a CAD system need to communicate positions which are constrained to lie on a surface. As the components may be developed by different suppliers, passing the positions as vectors is inefficient; as each component has to validate that the vector does lie on the surface.

For example, when a user selects a point on a model, the user interface component of a CAD application calls the modelling component to determine which face a ray hits. The modelling returns the face and a position on its surface. The user interface component later calls the modelling component again to ask for the surface normal at this position in order to determine the direction for an arrow on the display. The position might alternatively be passed to a feature modelling component, which will later use the position to select which portion of a divided face to keep.

In general the positions are communicated using the u, v coordinates of the surface parameterization. However, if the CAD system also wishes to treat facet meshes as surfaces, this causes a problem as facet meshes cannot be parameterized in the same way as a boundary representation model, as they may have a high topological genus, contain holes or be disjoint.

The natural method of representing positions on a mesh consists of an integer facet identifier and a pair of u, v coordinates providing a parameterization of the triangle. However, this means that the components cannot treat facet meshes and other types of surfaces homogenously. Any attempt to do so would require significant reengineering of any legacy system which wishes to extend its modelling capabilities to include facet meshes.

Previous solutions to this problem involve dividing the mesh into locally parameterizable regions, so that these local regions then can be given boundary representation type parameters. This is an expensive and complex procedure which involves imposing an arbitrary structure on the model. As this structure does not reflect any design intent, it can add unnecessary complexity to later operations.

This disclosure provides a mapping between the natural parameterization of the mesh and a u, v parameterization, of the type used in boundary representation models, by combining the integer identifier of the facet with the facet parameters. The use of a modified parameterisation allows a user input made in a boundary representation model to be mapped to data held only in mesh format, using the same mechanisms as classic surfaces. The method for combining the integer facet identifier with the triangle coordinates to provide a u, v parameterisation, reduces the chance that the amount of information exceeds the limits of floating point architecture

There are some limitations to the disclosed methods, for example, the resulting parameterization is not continuous, and the calculations on the parameters do not correspond to equivalent positional calculations. However, the method does enable components of the CAD application to communicate points on meshes using the same mechanism as the CAD applications uses for classic surfaces, so that it is possible to have a hybrid boundary representation model which incorporates mesh data without expensive and computing intensive conversion of the data format.

A barycentric coordinate system is used to define a parameterization for each facet. The three vertices x1, x2, x3 imply an origin at x1 and two axes u=(x2−x1) and v=(x3−x1). Every point P within the facet is uniquely defined by a sum P=x1+λu+μv, where triangle/barycentric coordinates λ, μ satisfy λ, μ≥0 and λ+μ≤1).

This is then combined with the facet identifier to give a u, v parameterization. For efficient translation between the two parameterizations, the external parameterization should be an affine transformation of the internal facet parameters of each facet, i.e. points, straight lines and planes are preserved in the transformation, so that all points lying on a line initially, still lie on a line after transformation, the midpoint of a line segment is still the midpoint after transformation and parallel lines remain parallel after transformation.

As many as possible of these affine images should be kept near to the parametric origin because the accuracy obtained decreases further away from the origin, and meshes may contain millions of facets. The double precision floating point format for representing real numbers has between 15 and 17 significant figures of accuracy, and the more significant figures that are used to specify the facet, the fewer that are available to specify the barycentric coordinates.

As is illustrated in FIG. 12, the integer facet identifiers, 1 to 32 in this figure, are mapped onto a spiral of unit squares around the origin. The number of integers shown is purely for illustration and in practice can become very large. Two facets are mapped to each square 70. Each unit square 70, as shown in FIG. 13 comprises two discrete triangles 71, i.e. one facet per triangle, and those triangles do not touch one another, or the boundary 72 of the unit square 70.

The consistency and compatibility with the existing mechanism for communicating positions on legacy surfaces significantly reduces the cost of adapting legacy CAD applications to facet geometry. A particular feature of the method described is that it allows customers to implement the functionality without rewriting their own software. Legacy models intended to work on a design built from boundary representation data are able to process surface mesh data without modification. The spiral and structural arrangement of the integer facet identifiers shown in FIG. 12 is an efficient way of operating the method.

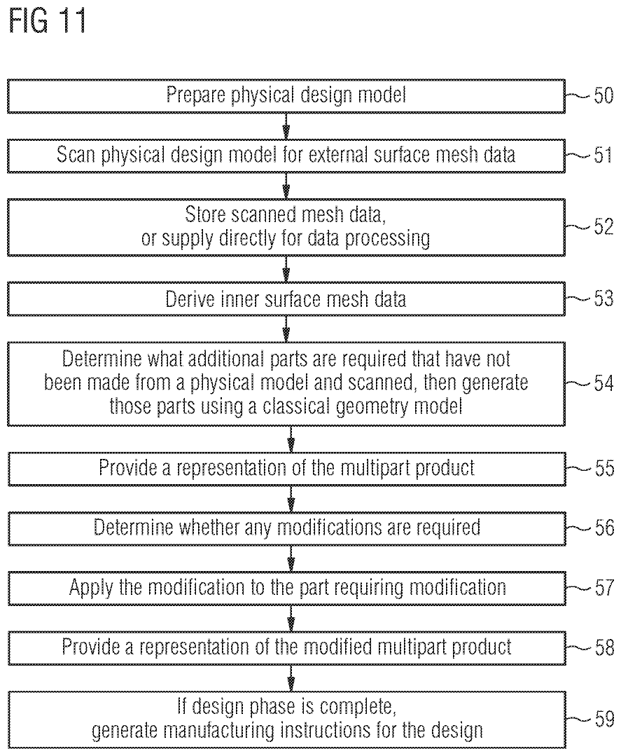

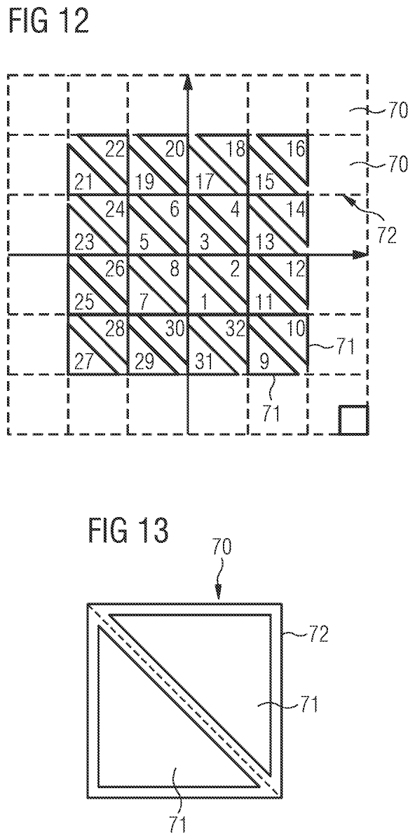

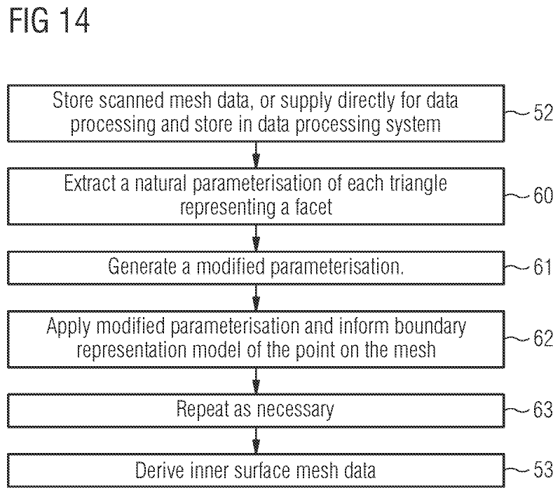

FIG. 14 is a flow diagram which provides more detail of the data processing steps which enable the method of modelling a product described in FIG. 11 to be carried out. Having obtained scanned facet based data in step 51, which is typically stored 52 in a store in the data processing system, a natural parameterisation of each triangle representing a facet is extracted 60. This natural parameterisation amounts to an integer facet identifier and a pair of u, v coordinates providing a parameterization of the triangle. As this amounts to three pieces of data rather than the two which are used in the boundary representation model, a modified parameterisation must be generated 61. The modification determines a unique point from the pair of u, v coordinates and uses the integer identifier with its unique point as the two parameters for communication with the boundary representation model 62. The process of generating modified parameters continues 63 as necessary until there is a full set of modified parameters to represent the facets of the scan data. In this example, the process step of deriving 53 inner surface mesh data may then be applied. However, more generally, once the modified parameterisation exists, then in response to a user clicking on a display of the mesh data at a particular point, the modified parameterisation is used to inform the boundary rep model of the point on the mesh surface of interest, so that it can provide a suitable response and update the image on the display for the user accordingly.

The present disclosure has a number of improvements over conventional methods of dealing with different requirements in product design.

Of course, those of skill in the art will recognize that, unless specifically indicated or required by the sequence of operations, certain steps in the processes described above may be omitted, performed concurrently or sequentially, or performed in a different order.

Those skilled in the art will recognize that, for simplicity and clarity, the full structure and operation of all data processing systems suitable for use with the present disclosure is not being depicted or described herein. Instead, only so much of a data processing system as is unique to the present disclosure or necessary for an understanding of the present disclosure is depicted and described. The remainder of the construction and operation of data processing system 21 may conform to any of the various current implementations and practices known in the art.

It is important to note that while the disclosure includes a description in the context of a fully functional system, those skilled in the art will appreciate that at least portions of the mechanism of the present disclosure are capable of being distributed in the form of instructions contained within a machine-usable, computer-usable, or computer-readable medium in any of a variety of forms, and that the present disclosure applies equally regardless of the particular type of instruction or signal bearing medium or storage medium utilized to actually carry out the distribution. Examples of machine usable/readable or computer usable/readable mediums include: nonvolatile, hard-coded type mediums such as read only memories (ROMs) or erasable, electrically programmable read only memories (EEPROMs), and user-recordable type mediums such as floppy disks, hard disk drives and compact disk read only memories (CD-ROMs) or digital versatile disks (DVDs).

Although an exemplary embodiment of the present disclosure has been described in detail, those skilled in the art will understand that various changes, substitutions, variations, and improvements disclosed herein may be made without departing from the spirit and scope of the disclosure in its broadest form.

None of the description in the present application should be read as implying that any particular element, step, or function is an essential element which must be included in the claim scope: the scope of patented subject matter is defined only by the allowed claims. Moreover, none of these claims are intended to invoke 35 USC § 112(f) unless the exact words “means for” are followed by a participle.

1.-22. (canceled)

23. A method of defining a point on a mesh representation of a part of a product and communicating the point to a boundary representation model, the method comprising:
obtaining a mesh data representation relating to a part of the product, the mesh data representation comprising a plurality of triangles each representing a facet;
extracting a natural parameterisation of each triangle of the mesh data representation, the natural parameterisation comprising an integer identifier of each facet and associated facet parameters, the facet parameters comprising a pair of u, v coordinates;
deriving a modified parameterisation for each triangle of the mesh data representation of the part comprising a combination of the integer identifier and the facet parameters;
communicating the modified parameterisation to the boundary representation model; and,
storing the modified parameterisation of the scan data.

24. The method according to claim 23,
wherein the step of deriving a modified parameterisation comprises:
identifying first, second and third vertices of each facet, identifying first and second axes of each facet and defining a unique point within the facet as the sum of the origin, a constant multiple of the first axis and a constant multiple of the second axis, where the constants are greater than or equal to zero and the sum of the constants is less than or equal to one.

25. The method according to claim 23, further comprising:
providing an updated representation of the modelled part.

26. The method according to claim 23, further comprising:
in response to a position request consequent to a user input receiving instructions of a selection of a point on the mesh representation of the modelled part, communicating the integer facet identifier and the unique point together to the boundary representation model to identify the point on the mesh.

27. The method according to claim 23,
wherein the integer facet identifiers are mapped onto a spiral of unit squares about the origin.

28. The method according to claim 27,
wherein two facets are mapped to each square.

29. The method according to claim 27,
wherein each triangle in the unit square is discrete and separated from a boundary of the unit square.

30. The method according to claim 23,
wherein the modified parameterisation comprises an affine transformation of the internal facet parameters of each facet.

31. The method according to claim 23,
wherein the mesh data is obtained from a physical sample of the part.

32. The method according to claim 31,
wherein the mesh data is derived by scanning the physical sample.

33. A data processing system comprising:
at least a processor and accessible memory,
the data processing system configured to define a point on a mesh representation of a part of a product and communicate the point to a boundary representation model, by executing a method comprising:
obtaining a mesh data representation relating to a part of the product from a physical sample of the part, the mesh data representation comprising a plurality of triangles;
extracting a natural parameterisation of each triangle of the mesh data representation, the natural parameterisation comprising an integer identifier of each facet and associated facet parameters, the facet parameters comprising a pair of u, v coordinates;
deriving a modified parameterisation for each triangle of the mesh data representation of the part comprising a combination of the integer identifier and the facet parameters;
communicating the modified parameterisation in response to a position request consequent to a user input receiving instructions of a selection of a point on the boundary representation model; and,
providing an updated representation of the modelled part.

34. The system according to claim 33, further comprising:
a display configured to output the representation of the modelled part.

35. The system according to claim 33, further comprising:
a store to store the representation of the modelled part.

36. A non-transitory computer-readable medium encoded with executable instructions that, when executed, cause one or more data processing systems to perform a method to define a point on a mesh representation of a part of a product and communicate the point to a boundary representation model, the method comprising:
obtaining a mesh data representation relating to a part of the product from a physical sample of the part, the mesh data representation comprising a plurality of triangles;
extracting a natural parameterisation of each triangle of the mesh data representation, the natural parameterisation comprising an integer identifier of each facet and associated facet parameters, the facet parameters comprising a pair of u, v coordinates;
deriving a modified parameterisation for each triangle of the mesh data representation of the part comprising a combination of the integer identifier and the facet parameters;
communicating the modified parameterisation in response to a position request consequent to a user input receiving instructions of a selection of a point on the boundary representation model; and,
providing an updated representation of the modelled part.
